(19) United States
(12) Patent Application Publication
(10) Pub. No.: US 2026/0293105 A1
(43) Pub. Date: Sep. 24, 2026

(54) SEMICONDUCTOR STORAGE DEVICE AND MANUFACTURING METHOD OF SEMICONDUCTOR STORAGE DEVICE

(71) Applicant: Kioxia Corporation, Tokyo (JP)

(72) Inventors: Daisuke WATANABE, Yokkaichi (JP); Akifumi GAWASE, Kuwana (JP); Takuya KIKUCHI, Yokkaichi (JP)

(21) Appl. No.: 19/326,217

(22) Filed: Sep. 11, 2025

(30) Foreign Application Priority Data
Mar. 24, 2025 (JP) 2025-048395

(51) Int. Cl. H10B 12/00

(52) U.S. Cl. CPC H10B 12/33; H10B 12/036

(57) ABSTRACT

A semiconductor storage device includes a capacitor including a first electrode, a second electrode, and a capacitor insulating film between the first electrode and the second electrode, and a transistor including a third electrode, a fourth electrode, an oxide semiconductor layer between the third electrode and the fourth electrode, and a gate electrode. The first electrode includes a first portion, a second portion, and a third portion. A chemical composition of the first portion is different from a chemical composition of the third portion, and a chemical composition of the second portion is different from the chemical composition of the third portion. The first portion is provided between the third portion and the third electrode in a first direction, and the second electrode includes a fourth portion. The second portion surrounds the fourth portion, and the fourth portion surrounds the first portion in a cross-section perpendicular to the first direction.

### CROSS-REFERENCE TO RELATED APPLICATION

This application is based upon and claims the benefit of priority from Japanese Patent Application No. 2025-048395, filed Mar. 24, 2025, the entire contents of which are incorporated herein by reference.

### FIELD

Embodiments described herein relate generally to a semiconductor storage device and a manufacturing method of a semiconductor storage device.

### BACKGROUND

Oxide semiconductor transistors, which form a channel in an oxide semiconductor layer, have an excellent property of having an extremely small channel leakage current during an off operation. For this reason, for example, oxide semiconductor transistors may be applied to a switching transistor in a memory cell of a dynamic random access memory (DRAM). When an oxide semiconductor transistor is applied to a switching transistor in a memory cell, an oxide semiconductor layer of the oxide semiconductor transistor is electrically connected to a storage node electrode of a capacitor.

### DESCRIPTION OF THE DRAWINGS

FIG. 1 is an equivalent circuit diagram of a semiconductor storage device according to a first embodiment.

FIG. 2 is a schematic cross-sectional view of the semiconductor storage device according to the first embodiment.

FIG. 3 is a schematic cross-sectional view of the semiconductor storage device according to the first embodiment.

FIG. 4 is a schematic cross-sectional view of the semiconductor storage device according to the first embodiment.

FIG. 5 is a schematic cross-sectional view of the semiconductor storage device according to the first embodiment.

FIG. 6 is a schematic cross-sectional view of the semiconductor storage device according to the first embodiment.

FIG. 7 is a schematic cross-sectional view of the semiconductor storage device according to the first embodiment.

FIG. 8 is a schematic cross-sectional view showing an example of a manufacturing method of the semiconductor storage device according to the first embodiment.

FIG. 9 is a schematic cross-sectional view showing an example of the manufacturing method of the semiconductor storage device according to the first embodiment.

FIG. 10 is a schematic cross-sectional view showing an example of the manufacturing method of the semiconductor storage device according to the first embodiment.

FIG. 11 is a schematic cross-sectional view showing an example of the manufacturing method of the semiconductor storage device according to the first embodiment.

FIG. 12 is a schematic cross-sectional view showing an example of the manufacturing method of the semiconductor storage device according to the first embodiment.

FIG. 13 is a schematic cross-sectional view showing an example of the manufacturing method of the semiconductor storage device according to the first embodiment.

FIG. 14 is a schematic cross-sectional view showing an example of the manufacturing method of the semiconductor storage device according to the first embodiment.

FIG. 15 is a schematic cross-sectional view showing an example of the manufacturing method of the semiconductor storage device according to the first embodiment.

FIG. 16 is a schematic cross-sectional view showing an example of the manufacturing method of the semiconductor storage device according to the first embodiment.

FIG. 17 is a schematic cross-sectional view showing an example of the manufacturing method of the semiconductor storage device according to the first embodiment.

FIG. 18 is a schematic cross-sectional view showing an example of the manufacturing method of the semiconductor storage device according to the first embodiment.

FIG. 19 is a schematic cross-sectional view showing an example of the manufacturing method of the semiconductor storage device according to the first embodiment.

FIG. 20 is a schematic cross-sectional view of a semiconductor storage device according to a comparative example.

FIG. 21 is a schematic cross-sectional view of a semiconductor storage device according to a first modification example of the first embodiment.

FIG. 22 is a schematic cross-sectional view of a semiconductor storage device according to a second modification example of the first embodiment.

FIG. 23 is a schematic cross-sectional view of a semiconductor storage device according to a second embodiment.

FIG. 24 is a schematic cross-sectional view showing an example of a manufacturing method of the semiconductor storage device according to the second embodiment.

FIG. 25 is a schematic cross-sectional view showing an example of the manufacturing method of the semiconductor storage device according to the second embodiment.

FIG. 26 is a schematic cross-sectional view showing an example of the manufacturing method of the semiconductor storage device according to the second embodiment.

FIG. 27 is a schematic cross-sectional view showing an example of the manufacturing method of the semiconductor storage device according to the second embodiment.

FIG. 28 is a schematic cross-sectional view showing an example of the manufacturing method of the semiconductor storage device according to the second embodiment.

FIG. 29 is a schematic cross-sectional view showing an example of the manufacturing method of the semiconductor storage device according to the second embodiment.

FIG. 30 is a schematic cross-sectional view showing an example of the manufacturing method of the semiconductor storage device according to the second embodiment.

### DETAILED DESCRIPTION

Embodiments provide a semiconductor storage device including an oxide semiconductor transistor.

In general, according to one embodiment, a semiconductor storage device includes a first capacitor that includes a first electrode, a second electrode, and a first capacitor insulating film provided between the first electrode and the second electrode, and a first transistor that includes a third electrode in contact with the second electrode, a fourth electrode, a first oxide semiconductor layer provided between the third electrode and the fourth electrode, a first gate electrode facing the first oxide semiconductor layer, and a first gate insulating film provided between the first gate electrode and the first oxide semiconductor layer, and is provided in a first direction with respect to the first capacitor, in which the first electrode includes a first portion, a second portion, and a third portion, a first chemical composition of the first portion is different from a third chemical composition of the third portion, a second chemical composition of the second portion is different from the third chemical composition of the third portion, the first portion is provided between the third portion and the third electrode in the first direction, the second electrode includes a fourth portion, and the second portion surrounds the fourth portion, and the fourth portion surrounds the first portion in a first cross-section perpendicular to the first direction and including the first electrode and the second electrode.

Hereinafter, embodiment of the present disclosure will be described with reference to the drawings. In the following description, the same or similar members are given the same reference numerals, and the description of already described members may be omitted as appropriate.

Further, in this specification, terms “upper”, “lower”, “upper portion”, “lower portion”, “upper side”, and “lower side” may be used for convenience. The terms “upper”, “lower”, “upper portion”, “lower portion”, “upper side”, and “lower side” are terms that indicate relative positional relationships in the drawings, and do not define positional relationships with respect to gravity.

In this specification, qualitative and quantitative analysis of chemical compositions of members that configure a semiconductor storage device may be performed using, for example, secondary ion mass spectrometry (SIMS), energy dispersive x-ray spectroscopy (EDX), or Rutherford back-scattering spectroscopy (RBS). In addition, for example, a transmission electron microscope (TEM) may be used to measure the thicknesses of members configuring the semiconductor storage device, distances between the members, crystal grain sizes, crystal orientation, and the like.

### First Embodiment

A semiconductor storage device according to a first embodiment includes a first capacitor that includes a first electrode, a second electrode, and a first capacitor insulating film provided between the first electrode and the second electrode, and a first transistor that includes a third electrode in contact with the second electrode, a fourth electrode, a first oxide semiconductor layer provided between the third electrode and the fourth electrode, a first gate electrode facing the first oxide semiconductor layer, and a first gate insulating film provided between the first gate electrode and the first oxide semiconductor layer, and that is provided in a first direction with respect to the first capacitor. The first electrode includes a first portion, a second portion, and a third portion, a first chemical composition of the first portion differs from a third chemical composition of the third portion, a second chemical composition of the second portion differs from a third chemical composition of the third portion, and the first portion is provided between the third portion and the third electrode in the first direction. The second electrode includes a fourth portion. In a first cross-section perpendicular to the first direction and including the first electrode and the second electrode, the second portion surrounds the fourth portion, and the fourth portion surrounds the first portion.

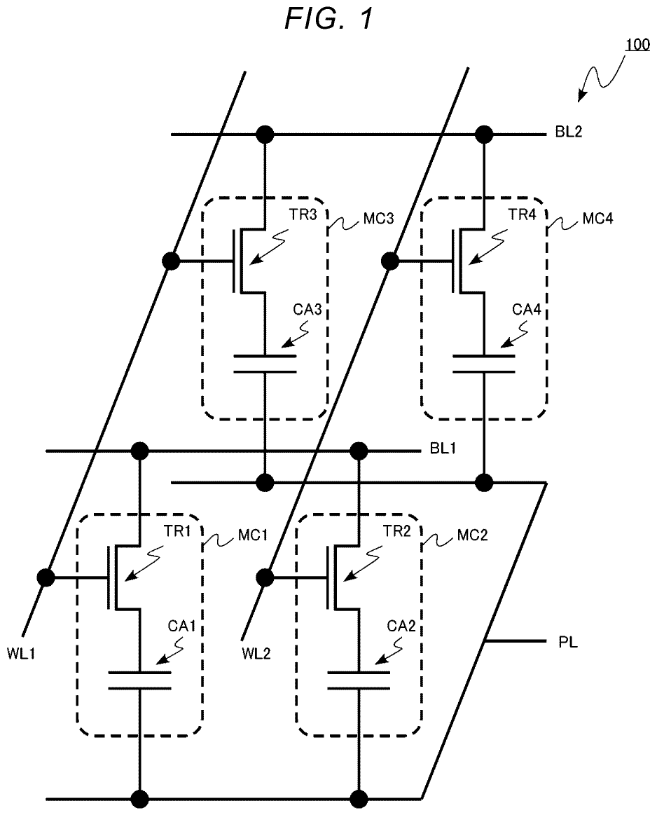

FIG. 1 is an equivalent circuit diagram of the semiconductor storage device according to the first embodiment. The semiconductor storage device according to the first embodiment is a semiconductor memory 100. The semiconductor memory 100 according to the first embodiment is a DRAM. The semiconductor memory 100 uses an oxide semiconductor transistor as a switching transistor in a memory cell of the DRAM.

FIG. 1 is a diagram showing a part of a memory cell array in the semiconductor memory 100. A plurality of memory cells are disposed in the memory cell array. Although FIG. 1 shows an example in which there are four memory cells, the number of memory cells in the memory cell array is not limited to four.

The memory cell array of the semiconductor memory 100 includes a plurality of memory cells MC1, MC2, MC3, and MC4, a plurality of word lines WL1 and WL2, a plurality of bit lines BL1 and BL2, and a plate line PL. The first memory cell MC1 includes a first transistor TR1 and a first capacitor CA1. The second memory cell MC2 includes a second transistor TR2 and a second capacitor CA2. The third memory cell MC3 includes a third transistor TR3 and a third capacitor CA3. The fourth memory cell MC4 includes a fourth transistor TR4 and a fourth capacitor CA4.

Hereinafter, one of the plurality of memory cells MC1, MC2, MC3, and MC4, or the plurality of memory cells MC1, MC2, MC3, and MC4 may be collectively referred to simply as a memory cell MC. In addition, one of the plurality of word lines WL1 and WL2, or the plurality of word lines WL1 and WL2 may be collectively referred to simply as a word line WL. In addition, one of the plurality of bit lines BL1 and BL2, or the plurality of bit lines BL1 and BL2 may be collectively referred to simply as a bit line BL.

Hereinafter, one of the first transistor TR1, the second transistor TR2, the third transistor TR3, and the fourth transistor TR4, or the first transistor TR1, the second transistor TR2, the third transistor TR3, and the fourth transistor TR4 will be collectively referred to simply as a transistor TR. In addition, one of the first capacitor CA1, the second capacitor CA2, the third capacitor CA3, and the fourth capacitor CA4, or the first capacitor CA1, the second capacitor CA2, the third capacitor CA3, and the fourth capacitor CA4 may be collectively referred to as a capacitor CA.

The word line WL is electrically connected to a gate electrode of the transistor TR. The bit line BL is electrically connected to one of source and drain electrodes of the transistor TR. The other of the source and drain electrodes of the transistor TR is electrically connected to one of the electrodes of the capacitor CA. The other electrode of the capacitor CA is connected to a plate line PL.

The memory cell MC stores data by storing charges in the capacitor CA. Data is written and read by turning on the transistor TR.

By selecting one bit line BL and one word line WL, one memory cell MC can be selected. For example, the transistor TR is turned on by applying a voltage to the word line WL in a state where a desired voltage is applied to the bit line BL, thereby writing data to the memory cell MC. In addition, for example, the transistor TR is turned on, and a voltage change in the bit line BL corresponding to the amount of charges stored in the capacitor CA is detected, thereby reading data from the memory cell MC.

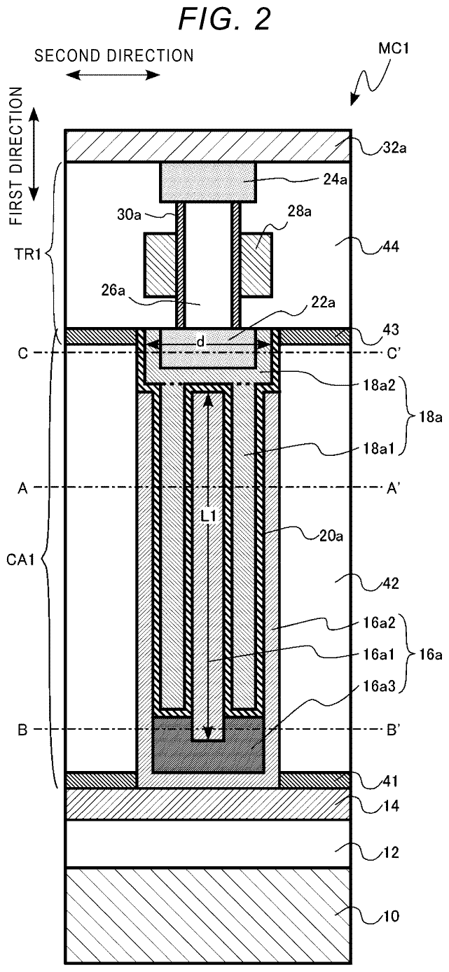

FIGS. 2, 3, 4, and 5 are schematic cross-sectional views of the semiconductor storage device according to the first embodiment. FIG. 2 shows a cross-section including the first memory cell MC1 in FIG. 1.

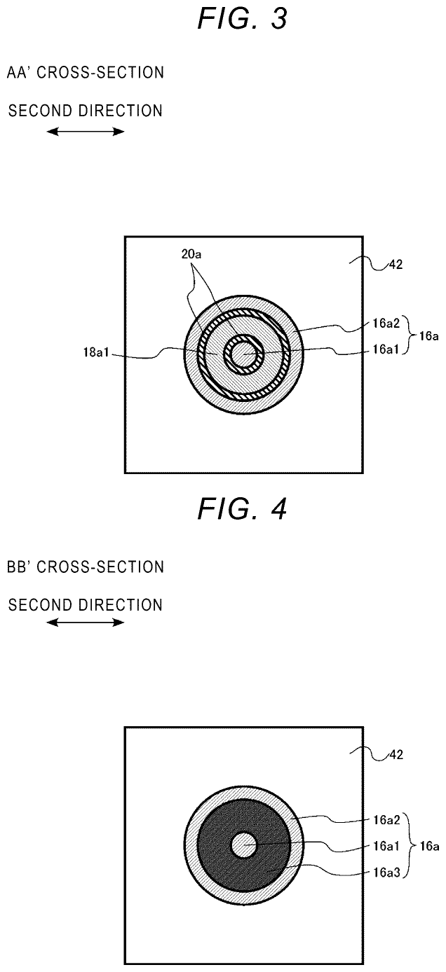

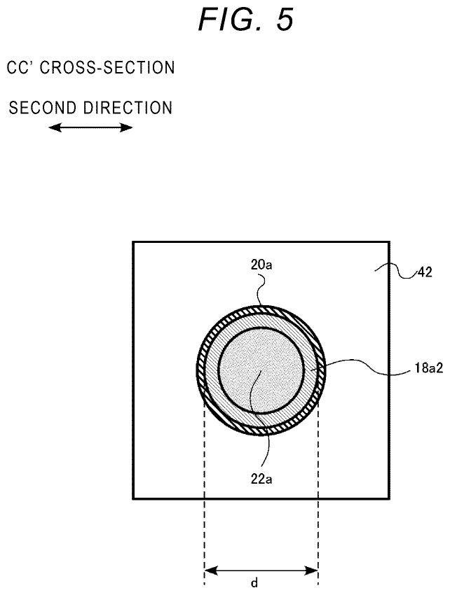

FIG. 3 is a cross-sectional view taken along line AA′ in FIG. 2. FIG. 4 is a cross-sectional view taken along line BB′ in FIG. 2. FIG. 5 is a cross-sectional view taken along line CC′ in FIG. 2. In FIG. 2, an up-down direction is referred to as a first direction. In FIG. 2, a right-left direction is referred to as a second direction. The second direction is perpendicular to the first direction.

The first memory cell MC1 of the semiconductor memory 100 according to the first embodiment includes the first capacitor CA1 and the first transistor TR1.

The semiconductor memory 100 according to the first embodiment includes a substrate 10, a substrate insulating layer 12, a plate conductive layer 14, a first plate electrode 16a, a first storage node electrode 18a, a first capacitor insulating film 20a, a first lower electrode 22a, a first upper electrode 24a, a first oxide semiconductor layer 26a, a first gate electrode 28a, a first gate insulating film 30a, a first wiring layer 32a, a first interlayer insulating layer 41, a second interlayer insulating layer 42, a third interlayer insulating layer 43, and a fourth interlayer insulating layer 44.

The first capacitor CA1 includes the first plate electrode 16a, the first storage node electrode 18a, and the first capacitor insulating film 20a. The first transistor TR1 includes the first lower electrode 22a, the first upper electrode 24a, the first oxide semiconductor layer 26a, the first gate electrode 28a, and the first gate insulating film 30a.

The first plate electrode 16a includes a pillar portion 16a1, an outer portion 16a2, and a bottom portion 16a3.

The first storage node electrode 18a includes a lower portion 18a1 and an upper portion 18a2.

The plate conductive layer 14 is an example of a first conductive layer. The first plate electrode 16a is an example of a first electrode. The first storage node electrode 18a is an example of a second electrode. The first lower electrode 22a is an example of a third electrode. The first upper electrode 24a is an example of a fourth electrode. The first wiring layer 32a is an example of a second conductive layer.

The pillar portion 16a1 is an example of a first portion. The outer portion 16a2 is an example of a second portion. The bottom portion 16a3 is an example of a third portion. The lower portion 18a1 is an example of a fourth portion. The upper portion 18a2 is an example of a fifth portion.

The substrate 10 is, for example, a semiconductor substrate. The substrate 10 is, for example, a silicon substrate. For example, an insulator substrate may be used as the substrate 10. The substrate 10 may also be omitted.

The memory cell array is provided on the substrate 10. The first capacitor CA1 and the first transistor TR1 are provided on the substrate 10. The first transistor TR1 is provided in a first direction with respect to the first capacitor CA1. The first capacitor CA1 is provided between the substrate 10 and the first transistor TR1.

The substrate insulating layer 12 is provided on the substrate 10. The substrate insulating layer 12 is provided between the substrate 10 and the plate conductive layer 14. The substrate insulating layer 12 is an insulator. The substrate insulating layer 12 is, for example, silicon oxide.

The plate conductive layer 14 is provided on the substrate insulating layer 12. The plate conductive layer 14 is a conductor. The plate conductive layer 14 contains, for example, a metal or a metal compound. The plate conductive layer 14 is, for example, tungsten.

The plate conductive layer 14 corresponds to the plate line PL in the equivalent circuit diagram of FIG. 1.

The first capacitor CA1 includes the first plate electrode 16a, the first storage node electrode 18a, and the first capacitor insulating film 20a.

The first plate electrode 16a is provided on the plate conductive layer 14. The first plate electrode 16a is, for example, electrically connected to the plate conductive layer 14. The first plate electrode 16a is in contact with the plate conductive layer 14, for example.

The first plate electrode 16a includes the pillar portion 16a1, the outer portion 16a2, and the bottom portion 16a3.

The pillar portion 16a1 has a pillar shape. The pillar portion 16a1 extends in the first direction.

The outer portion 16a2 configures the outer periphery and bottom of the first plate electrode 16a. The outer portion 16a2 surrounds the pillar portion 16a1 in a cross-section perpendicular to the first direction. The outer portion 16a2 surrounds the bottom portion 16a3 in another cross-section perpendicular to the first direction.

The outer portion 16a2 is in contact with the plate conductive layer 14.

The bottom portion 16a3 configures the bottom of the first plate electrode 16a. The bottom portion 16a3 is provided between the outer portion 16a2 and the pillar portion 16a1 in the first direction. The bottom portion 16a3 is in contact with the outer portion 16a2 and the pillar portion 16a1.

In the first direction, the pillar portion 16a1 is provided between the bottom portion 16a3 and the first lower electrode 22a.

The length (L1 in FIG. 2) of the pillar portion 16a1 in the first direction is, for example, equal to or more than 10 times and equal to or less than 20 times the outer diameter (d in FIG. 2 and FIG. 5) of the upper portion 18a2. The outer diameter is, for example, a length of the upper portion 18a2 in the second direction. The length L1 of the pillar portion 16a1 in the first direction is, for example, equal to or more than 500 nm and equal to or less than 1500 nm. The outer diameter d of the upper portion 18a2 is, for example, equal to or more than 30 nm and equal to or less than 80 nm.

The pillar portion 16a1, the outer portion 16a2, and the bottom portion 16a3 are conductors. The pillar portion 16a1, the outer portion 16a2, and the bottom portion 16a3 contain, for example, a metal or a metal compound.

The pillar portion 16a1 has a first chemical composition. The pillar portion 16a1 contains, for example, a first material. The pillar portion 16a1 is formed, for example, of the first material.

The outer portion 16a2 has a second chemical composition. The outer portion 16a2 contains, for example, a second material. The outer portion 16a2 is formed of, for example, the second material.

The bottom portion 16a3 has a third chemical composition. The bottom portion 16a3 contains, for example, a third material. The bottom portion 16a3 is formed of, for example, the third material.

The first chemical composition of the pillar portion 16a1 is different from the third chemical composition of the bottom portion 16a3. In addition, the second chemical composition of the outer portion 16a2 is different from the third chemical composition of the bottom portion 16a3.

The first chemical composition of the pillar portion 16a1 is, for example, the same as the second chemical composition of the outer portion 16a2. In addition, the first chemical composition of the pillar portion 16a1 is, for example, different from the second chemical composition of the outer portion 16a2.

The first material contained in the pillar portion 16a1 is, for example, different from the third material contained in the bottom portion 16a3. The second material contained in the outer portion 16a2 is, for example, different from the third material contained in the bottom portion 16a3.

The first material contained in the pillar portion 16a1 is, for example, the same as the second material contained in the outer portion 16a2. The first material contained in the pillar portion 16a1 is, for example, different from the second material contained in the outer portion 16a2.

The pillar portion 16a1 contains, for example, titanium nitride. Titanium nitride is an example of the first material.

The outer portion 16a2 contains, for example, titanium nitride. Titanium nitride is an example of the second material.

The bottom portion 16a3 contains, for example, tungsten or molybdenum. Tungsten or molybdenum is an example of the third material. The bottom portion 16a3 contains, for example, tungsten containing at least one element selected from the group including boron (B), nitrogen (N), aluminum (Al), and scandium (Sc). Tungsten containing at least one element selected from the group including boron (B), nitrogen (N), aluminum (Al), and scandium (Sc) is an example of the third material.

The first storage node electrode 18a is provided on the first plate electrode 16a. The first storage node electrode 18a is provided between the first plate electrode 16a and the first lower electrode 22a. The first storage node electrode 18a is in contact with the first lower electrode 22a.

The first storage node electrode 18a includes the lower portion 18a1 and the upper portion 18a2. The upper portion 18a2 is provided between the lower portion 18a1 and the first lower electrode 22a. The upper portion 18a2 is in contact with the first lower electrode 22a.

The lower portion 18a1 has a cylindrical shape extending in the first direction.

The first storage node electrode 18a is a conductor. The first storage node electrode 18a contains, for example, a metal or a metal compound.

The lower portion 18a1 and the upper portion 18a2 contain, for example, the same material. The lower portion 18a1 and the upper portion 18a2 are formed of, for example, the same material.

The first storage node electrode 18a contains, for example, titanium nitride. The first storage node electrode 18a is formed, for example, of titanium nitride.

The first capacitor insulating film 20a is provided between the first plate electrode 16a and the first storage node electrode 18a. The first capacitor insulating film 20a is in contact with the first plate electrode 16a and the first storage node electrode 18a.

The first capacitor insulating film 20a is an insulator. The first capacitor insulating film 20a includes, for example, an insulator having a dielectric constant higher than that of silicon dioxide. The first capacitor insulating film 20a includes, for example, a so-called High-k insulator.

The first capacitor insulating film 20a contains, for example, zirconium oxide. The first capacitor insulating film 20a has, for example, a stacked structure of zirconium oxide, aluminum oxide, and zirconium oxide.

As shown in FIG. 3, in an AA′ cross-section perpendicular to the first direction and including the first plate electrode 16a and the first storage node electrode 18a, the outer portion 16a2 of the first plate electrode 16a surrounds the lower portion 18a1 of the first storage node electrode 18a. In addition, in the AA′ cross-section, the lower portion 18a1 surrounds the pillar portion 16a1 of the first plate electrode 16a. The AA′ cross-section is an example of a first cross-section.

In the AA′ cross-section, the first capacitor insulating film 20a is provided between the outer portion 16a2 and the lower portion 18a1. In the AA′ cross-section, the first capacitor insulating film 20a is provided between the lower portion 18a1 and the pillar portion 16a1.

As shown in FIG. 4, in a BB′ cross-section perpendicular to the first direction and including the pillar portion 16a1, the outer portion 16a2, and the bottom portion 16a3, the outer portion 16a2 surrounds the bottom portion 16a3. Further, in the BB′ cross-section, the bottom portion 16a3 surrounds the pillar portion 16a1. The BB′ cross-section is an example of a second cross-section.

In the BB′ cross-section, the outer portion 16a2 is in contact with the bottom portion 16a3. Further, in the BB′ cross-section, the bottom portion 16a3 is in contact with the pillar portion 16a1.

As shown in FIG. 5, in a CC′ cross-section perpendicular to the first direction and including the upper portion 18a2 of the first storage node electrode 18a and the first lower electrode 22a, the upper portion 18a2 surrounds the first lower electrode 22a. In the CC′ cross-section, the upper portion 18a2 is in contact with the first lower electrode 22a. The CC′ cross-section is an example of a third cross-section.

In the CC′ cross-section, the first capacitor insulating film 20a surrounds the upper portion 18a2. In the CC′ cross-section, the first capacitor insulating film 20a is in contact with the upper portion 18a2.

The first transistor TR1 includes the first lower electrode 22a, the first upper electrode 24a, the first oxide semiconductor layer 26a, the first gate electrode 28a, and the first gate insulating film 30a.

The first lower electrode 22a and the first upper electrode 24a function as source and drain electrodes of the first transistor TR1.

The first lower electrode 22a is in contact with the first storage node electrode 18a. The first lower electrode 22a is electrically connected to the first storage node electrode 18a.

The first lower electrode 22a and the first upper electrode 24a are conductors. The first lower electrode 22a or the first upper electrode 24a includes, for example, an oxide conductor.

The first lower electrode 22a or the first upper electrode 24a contains at least one metal element selected from the group including, for example, indium (In), gallium (Ga), zinc (Zn), magnesium (Mg), aluminum (Al), manganese (Mn), tin (Sn), titanium (Ti), tantalum (Ta), calcium (Ca), tungsten (W), and molybdenum (Mo), and oxygen (O). The first lower electrode 22a or the first upper electrode 24a contains, for example, indium (In), tin (Sn), and oxygen (O). The first lower electrode 22a or the first upper electrode 24a contains, for example, indium tin oxide. The first lower electrode 22a or the first upper electrode 24a is, for example, indium tin oxide.

The first lower electrode 22a or the first upper electrode 24a contains, for example, a metal, a metal nitride, or a metal carbide. The first lower electrode 22a or the first upper electrode 24a contains, for example, one metal element selected from the group including tungsten (W), molybdenum (Mo), copper (Cu), aluminum (Al), titanium (Ti), and tantalum (Ta). The first lower electrode 22a or the first upper electrode 24a contains, for example, at least one metal element selected from the group including titanium (Ti), tungsten (W), molybdenum (Mo), and tantalum (Ta), and nitrogen (N). The first lower electrode 22a or the first upper electrode 24a contains, for example, titanium nitride, tungsten nitride, molybdenum nitride, or tantalum nitride. The first lower electrode 22a or the first upper electrode 24a contains, for example, at least one metal element selected from the group including titanium (Ti), tungsten (W), molybdenum (Mo), and tantalum (Ta), and carbon (C). The first lower electrode 22a or the first upper electrode 24a contains, for example, titanium carbide, tungsten carbide, molybdenum carbide, or tantalum carbide.

The first lower electrode 22a or the first upper electrode 24a may be, for example, a stacked structure of two or more types of materials. The first lower electrode 22a or the first upper electrode 24a may be, for example, a stacked structure of a metal nitride and an oxide conductor.

The first oxide semiconductor layer 26a is provided between the first lower electrode 22a and the first upper electrode 24a.

The first oxide semiconductor layer 26a is electrically connected to the first lower electrode 22a and the first upper electrode 24a. The first oxide semiconductor layer 26a is in contact with, for example, the first lower electrode 22a and the first upper electrode 24a. The first oxide semiconductor layer 26a extends in the first direction.

In the first oxide semiconductor layer 26a, a channel serving as a current path is formed when the first transistor TR1 is turned on.

The first oxide semiconductor layer 26a is an oxide semiconductor. The first oxide semiconductor layer 26a is, for example, amorphous.

The first oxide semiconductor layer 26a contains, for example, at least one metal element selected from the group including indium (In), gallium (Ga), zinc (Zn), magnesium (Mg), aluminum (Al), manganese (Mn), tin (Sn), titanium (Ti), calcium (Ca), and cadmium (Cd), and oxygen (O).

The first oxide semiconductor layer 26a contains, for example, at least one element selected from the group including zinc (Zn), gallium (Ga), silicon (Si), aluminum (Al), and tin (Sn), and indium (In), and oxygen (O). The first oxide semiconductor layer 26a contains, for example, indium (In), gallium (Ga), zinc (Zn), and oxygen (O). The first oxide semiconductor layer 26a contains, for example, indium gallium zinc oxide. The first oxide semiconductor layer 26a is, for example, indium gallium zinc oxide.

The first oxide semiconductor layer 26a contains, for example, oxygen vacancies. The oxygen vacancies in the first oxide semiconductor layer 26a function as donors.

The first gate electrode 28a faces the first oxide semiconductor layer 26a. The first gate electrode 28a surrounds the first oxide semiconductor layer 26a, for example, in a cross-section perpendicular to the first direction. The first gate electrode 28a is provided, for example, in the vicinity of the first oxide semiconductor layer 26a. The first transistor TR1 is, for example, a so-called gate all around (GAA) transistor. The first transistor TR1 is not limited to a configuration in which the first gate electrode 28a surrounds the first oxide semiconductor layer 26a in a cross-section perpendicular to the first direction. The first transistor TR1 may have a configuration in which the first gate electrode 28a faces only a part of the first oxide semiconductor layer 26a in a cross-section perpendicular to the first direction.

The first gate electrode 28a is a conductor. The first gate electrode 28a is, for example, a metal, a metal compound, or a semiconductor. The first gate electrode 28a contains, for example, tungsten (W). The first gate electrode 28a is, for example, tungsten.

The first gate electrode 28a corresponds to the word line WL in the equivalent circuit diagram of FIG. 1. For example, the first gate electrode 28a corresponds to the first word line WL1.

The first gate insulating film 30a is provided between the first gate electrode 28a and the first oxide semiconductor layer 26a. The first gate insulating film 30a is provided between the first lower electrode 22a and the first upper electrode 24a. The first gate insulating film 30a is in contact with, for example, the first lower electrode 22a and the first upper electrode 24a.

The first gate insulating film 30a is an insulator. The first gate insulating film 30a contains, for example, silicon (Si) and oxygen (O), or silicon (Si) and nitrogen (N). The first gate insulating film 30a contains, for example, silicon oxide or silicon nitride. The first gate insulating film 30a is, for example, a stacked film of a silicon oxide film and a silicon nitride film.

The first wiring layer 32a is provided on the first transistor TR1. The first wiring layer 32a extends in the second direction. The first wiring layer 32a is provided on the first upper electrode 24a. The first wiring layer 32a is electrically connected to the first upper electrode 24a. The first wiring layer 32a is in contact with the first upper electrode 24a.

The first wiring layer 32a is a conductor. The first wiring layer 32a contains, for example, a metal or a metal compound. The first wiring layer 32a contains, for example, at least one metal element selected from the group including titanium (Ti), tantalum (Ta), tungsten (W), and molybdenum (Mo). The first wiring layer 32a has, for example, a stacked structure of titanium nitride and tungsten.

The first wiring layer 32a corresponds to the bit line BL in the equivalent circuit diagram of FIG. 1. For example, the first wiring layer 32a corresponds to the first bit line BL1.

The first interlayer insulating layer 41, the second interlayer insulating layer 42, the third interlayer insulating layer 43, and the fourth interlayer insulating layer 44 are provided around the memory cell MC. The first interlayer insulating layer 41 is provided on the plate conductive layer 14. The second interlayer insulating layer 42 is provided on the first interlayer insulating layer 41. The third interlayer insulating layer 43 is provided on the second interlayer insulating layer 42. The fourth interlayer insulating layer 44 is provided on the third interlayer insulating layer 43.

The first interlayer insulating layer 41, the second interlayer insulating layer 42, the third interlayer insulating layer 43, and the fourth interlayer insulating layer 44 are provided around the first memory cell MC1.

As shown in FIG. 3, in the AA′ cross-section perpendicular to the first direction and including the first plate electrode 16a and the first storage node electrode 18a, the outer portion 16a2 of the first plate electrode 16a is surrounded by the second interlayer insulating layer 42. In the AA′ cross-section, the outer portion 16a2 is in contact with the second interlayer insulating layer 42.

The first interlayer insulating layer 41, the second interlayer insulating layer 42, the third interlayer insulating layer 43, and the fourth interlayer insulating layer 44 are insulators. The first interlayer insulating layer 41, the second interlayer insulating layer 42, the third interlayer insulating layer 43, and the fourth interlayer insulating layer 44 contain, for example, silicon oxide or silicon nitride.

The first interlayer insulating layer 41 and the third interlayer insulating layer 43 contain, for example, silicon nitride. The second interlayer insulating layer 42 and the fourth interlayer insulating layer 44 contain, for example, silicon oxide.

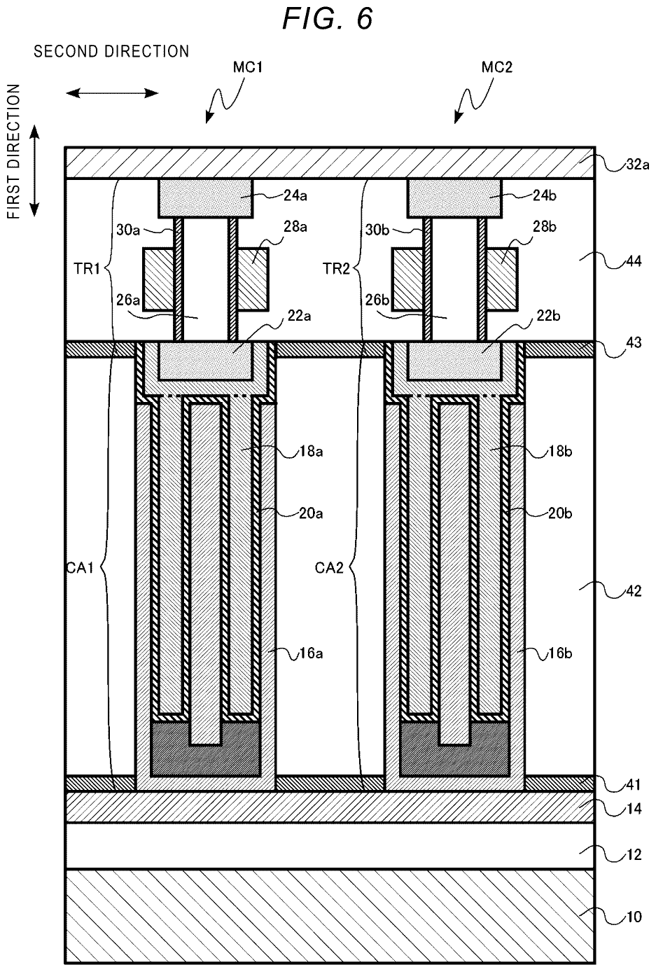

FIG. 6 is a schematic cross-sectional view of the semiconductor storage device according to the first embodiment. FIG. 6 shows a cross-section including the first memory cell MC1 and the second memory cell MC2 in FIG. 1.

In FIG. 6, the up-down direction is referred to as a first direction. In FIG. 6, the right-left direction is referred to as a second direction. The second direction is perpendicular to the first direction.

The second memory cell MC2 of the semiconductor memory 100 according to the first embodiment includes the second capacitor CA2 and the second transistor TR2.

The second memory cell MC2 has a structure similar to that of the first memory cell MC1. The second capacitor CA2 has a structure similar to that of the first capacitor CA1. The second transistor TR2 has a structure similar to that of the first transistor TR1.

The second capacitor CA2 includes a second plate electrode 16b, a second storage node electrode 18b, and a second capacitor insulating film 20b. The second transistor TR2 includes a second lower electrode 22b, a second upper electrode 24b, a second oxide semiconductor layer 26b, a second gate electrode 28b, and a second gate insulating film 30b.

The second plate electrode 16b is an example of a fifth electrode. The second storage node electrode 18b is an example of a sixth electrode. The second lower electrode 22b is an example of a seventh electrode. The second upper electrode 24b is an example of an eighth electrode.

The first plate electrode 16a and the second plate electrode 16b are electrically connected to the plate conductive layer 14. The first plate electrode 16a and the second plate electrode 16b are in contact with the plate conductive layer 14.

The first upper electrode 24a and the second upper electrode 24b are electrically connected to the first wiring layer 32a. The first upper electrode 24a and the second upper electrode 24b are in contact with the first wiring layer 32a.

The plate conductive layer 14 corresponds to the plate line PL in the equivalent circuit diagram of FIG. 1.

The first gate electrode 28a and the second gate electrode 28b correspond to the word line WL in the equivalent circuit diagram of FIG. 1. For example, the first gate electrode 28a corresponds to the first word line WL1. For example, the second gate electrode 28b corresponds to the second word line WL2.

The first wiring layer 32a corresponds to the bit line BL in the equivalent circuit diagram of FIG. 1. For example, the first wiring layer 32a corresponds to the first bit line BL1.

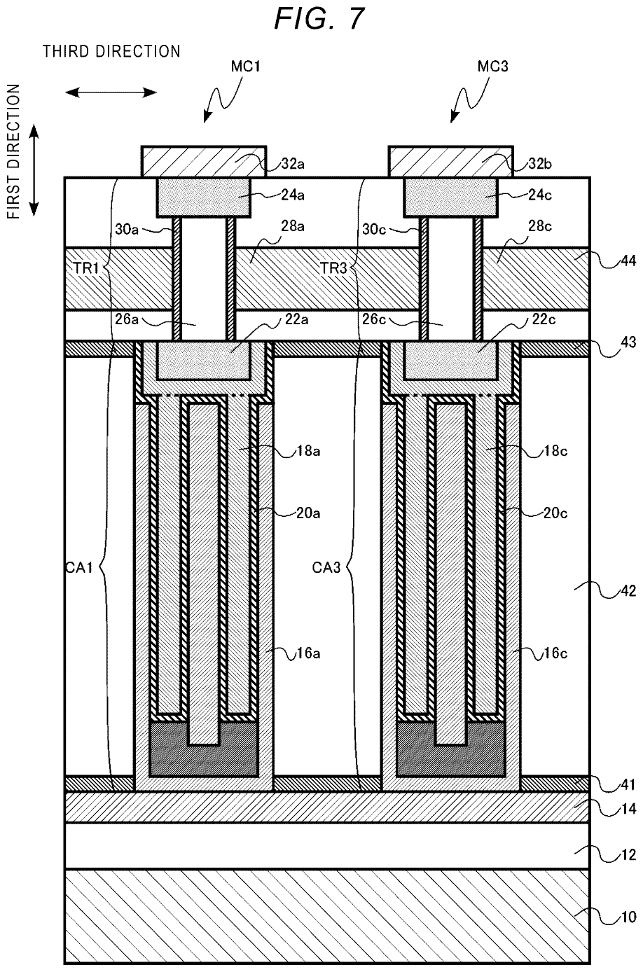

FIG. 7 is a schematic cross-sectional view of the semiconductor storage device according to the first embodiment. FIG. 7 shows a cross-section including the first memory cell MC1 and the third memory cell MC3 in FIG. 1.

In FIG. 7, the up-down direction is referred to as a first direction. In FIG. 7, the right-left direction is referred to as a third direction. The third direction is perpendicular to the first direction and the second direction.

The semiconductor memory 100 according to the first embodiment includes a second wiring layer 32b.

The third memory cell MC3 of the semiconductor memory 100 according to the first embodiment includes the third capacitor CA3 and the third transistor TR3.

The third memory cell MC3 has a structure similar to that of the first memory cell MC1. The third capacitor CA3 has a structure similar to that of the first capacitor CA1. The third transistor TR3 has a structure similar to that of the first transistor TR1.

The third capacitor CA3 includes a third plate electrode 16c, a third storage node electrode 18c, and a third capacitor insulating film 20c. The third transistor TR3 includes a third lower electrode 22c, a third upper electrode 24c, a third oxide semiconductor layer 26c, a third gate electrode 28c, and a third gate insulating film 30c.

The third plate electrode 16c is an example of a ninth electrode. The third storage node electrode 18c is an example of a tenth electrode. The third lower electrode 22c is an example of an eleventh electrode. The third upper electrode 24c is an example of a twelfth electrode.

The first plate electrode 16a and the third plate electrode 16c are electrically connected to the plate conductive layer 14. The first plate electrode 16a and the third plate electrode 16c are in contact with the plate conductive layer 14.

The first upper electrode 24a is electrically connected to the first wiring layer 32a. The first upper electrode 24a is in contact with the first wiring layer 32a.

The third upper electrode 24c is electrically connected to the second wiring layer 32b. The third upper electrode 24c is in contact with the second wiring layer 32b.

The first gate electrode 28a and the third gate electrode 28c are electrically connected to each other. The first gate electrode 28a and the third gate electrode 28c are, for example, physically continuous.

The plate conductive layer 14 corresponds to the plate line PL in the equivalent circuit diagram of FIG. 1.

The first gate electrode 28a and the third gate electrode 28c correspond to the word line WL in the equivalent circuit diagram of FIG. 1. For example, the first gate electrode 28a and the third gate electrode 28c correspond to the first word line WL1.

The first wiring layer 32a corresponds to the bit line BL in the equivalent circuit diagram of FIG. 1. For example, the first wiring layer 32a corresponds to the first bit line BL1. The second wiring layer 32b corresponds to the bit line BL in the equivalent circuit diagram of FIG. 1. For example, the second wiring layer 32b corresponds to the second bit line BL2.

Next, an example of a manufacturing method of the semiconductor storage device according to the first embodiment will be described.

The manufacturing method of the semiconductor storage device according to the first embodiment includes forming an opening in a first insulating layer, forming a first conductive film in the opening, forming a second conductive film having a chemical composition different from that of the first conductive film on the first conductive film in the opening, forming a third conductive film having a chemical composition different from that of the second conductive film on the second conductive film in the opening to fill the opening, removing the third conductive film, the second conductive film, and the first conductive film on a surface of the first insulating layer, selectively removing an upper portion of the first conductive film and an upper portion of the third conductive film in the opening with respect to the second conductive film, selectively removing a portion of the second conductive film in the opening with respect to the first conductive film and the third conductive film to form a pillar structure of the third conductive film, forming an insulating film on the first conductive film, the second conductive film, and the third conductive film in the opening, and forming a fourth conductive film on the insulating film in the opening to fill a space between the first conductive film and the pillar structure.

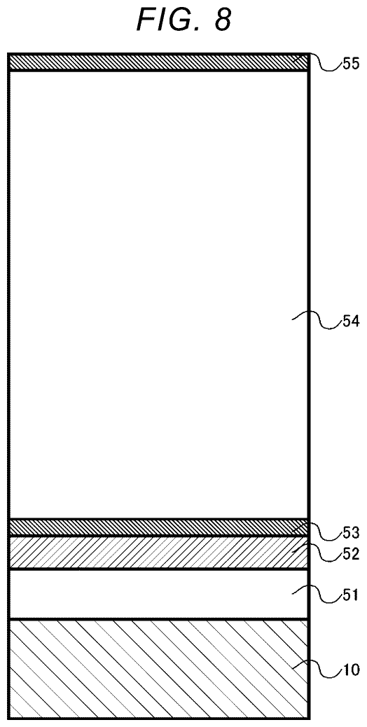

FIGS. 8, 9, 10, 11, 12, 13, 14, 15, 16, 17, 18, and 19 are schematic cross-sectional views showing an example of a manufacturing method of the semiconductor storage device according to the first embodiment. Each of FIGS. 8 to 19 shows a cross-section corresponding to FIG. 2. Each of FIGS. 8 to 19 shows an example of the manufacturing method of the semiconductor memory 100.

The following is a description of an example in which the substrate insulating layer 12 is made of silicon oxide, the plate conductive layer 14 is made of tungsten, the pillar portion 16a1 of the first plate electrode 16a is made of titanium nitride, the outer portion 16a2 of the first plate electrode 16a is made of titanium nitride, the bottom portion 16a3 of the first plate electrode 16a is made of boron-containing tungsten, the first storage node electrode 18a is made of titanium nitride, the first capacitor insulating film 20a is made of zirconium oxide, the first lower electrode 22a is made of indium tin oxide, the first interlayer insulating layer 41 and the third interlayer insulating layer 43 are made of silicon nitride, and the second interlayer insulating layer 42 is made of silicon oxide. The bottom portion 16a3 may be made of tungsten containing nitrogen, tungsten containing aluminum, or tungsten containing scandium.

First, a first silicon oxide film 51, a tungsten film 52, a first silicon nitride film 53, a second silicon oxide film 54, and a second silicon nitride film 55 are formed on the substrate 10 (FIG. 8). The first silicon oxide film 51, the tungsten film 52, the first silicon nitride film 53, the second silicon oxide film 54, and the second silicon nitride film 55 are formed, for example, by a chemical vapor deposition method (CVD method). The first silicon nitride film 53, the second silicon oxide film 54, and the second silicon nitride film 55 are examples of a first insulating layer.

The first silicon oxide film 51 eventually becomes the substrate insulating layer 12. The tungsten film 52 eventually becomes the plate conductive layer 14. A part of the first silicon nitride film 53 eventually becomes the first interlayer insulating layer 41. A part of the second silicon oxide film 54 eventually becomes the second interlayer insulating layer 42. A part of the second silicon nitride film 55 eventually becomes the third interlayer insulating layer 43.

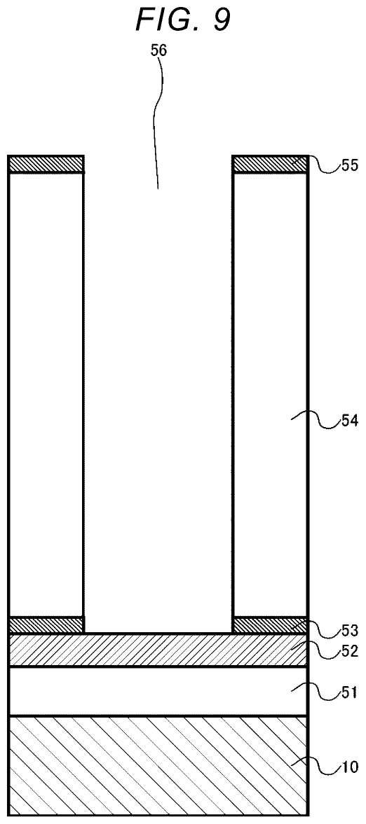

Next, the opening 56 that penetrates the second silicon nitride film 55, the second silicon oxide film 54, and the first silicon nitride film 53 and reaches the tungsten film 52 is formed (FIG. 9). The opening 56 is formed, for example, by using a lithography method and a reactive ion etching (RIE) method.

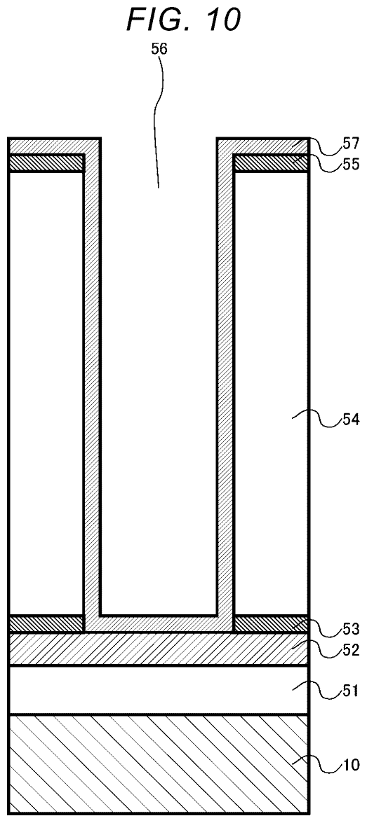

Next, a first titanium nitride film 57 is formed in the opening 56 (FIG. 10). The first titanium nitride film 57 is formed, for example, by using an atomic layer deposition method (ALD method). The first titanium nitride film 57 is an example of a first conductive film. A part of the first titanium nitride film 57 eventually becomes the outer portion 16a2 of the first plate electrode 16a.

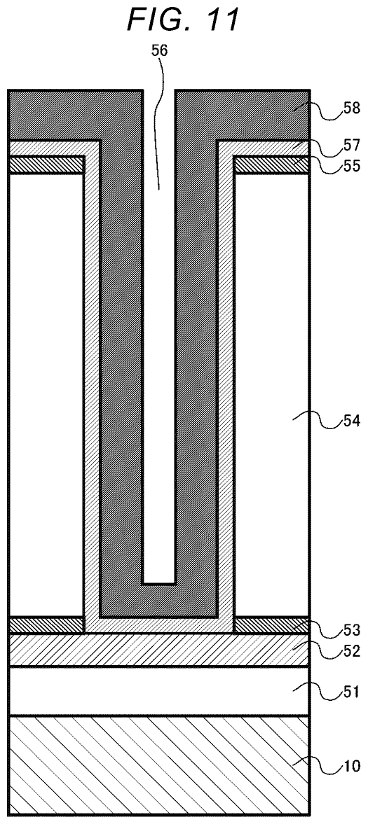

Next, a boron-containing tungsten film 58 is formed on the first titanium nitride film 57 in the opening 56 (FIG. 11). The boron-containing tungsten film 58 is formed, for example, by using a CVD method. For example, when forming a tungsten film, diborane (B₂H₆) is used to form a nucleation layer on the first titanium nitride film 57, thereby forming the boron-containing tungsten film 58. The boron-containing tungsten film 58 is an example of a second conductive film. A part of the boron-containing tungsten film 58 eventually becomes the bottom portion 16a3 of the first plate electrode 16a.

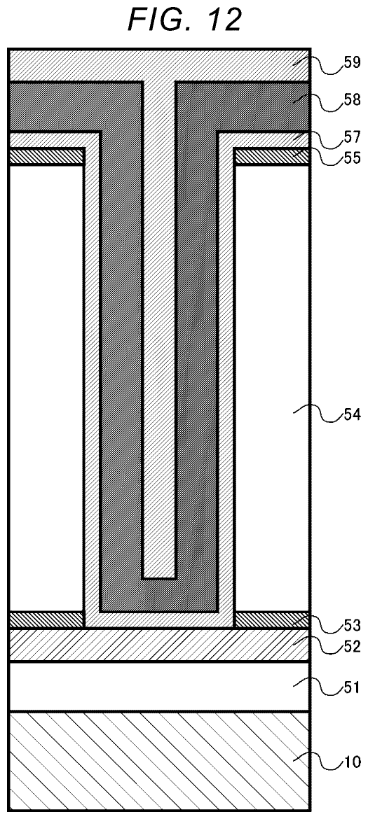

Next, a second titanium nitride film 59 is formed on the boron-containing tungsten film 58 in the opening 56, thereby filling the opening 56 (FIG. 12). The second titanium nitride film 59 is formed, for example, by using an ALD method. The second titanium nitride film 59 is an example of a third conductive film. A part of the second titanium nitride film 59 eventually becomes the pillar portion 16a1 of the first plate electrode 16a.

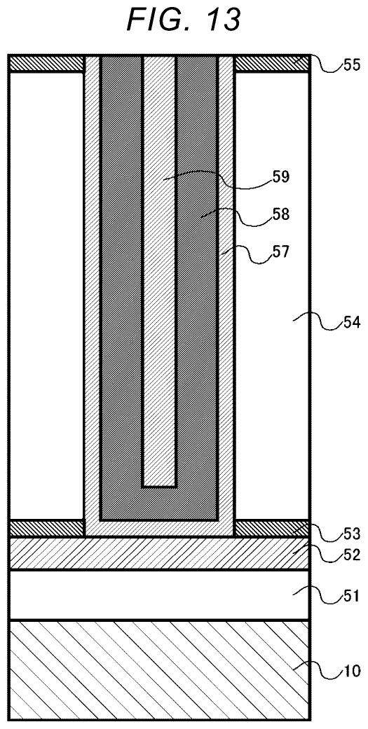

Next, the second titanium nitride film 59, the boron-containing tungsten film 58, and the first titanium nitride film 57 on the surface of the second silicon nitride film 55 are removed (FIG. 13). The second titanium nitride film 59, the boron-containing tungsten film 58, and the first titanium nitride film 57 are removed, for example, by using a chemical mechanical polishing (CMP) method.

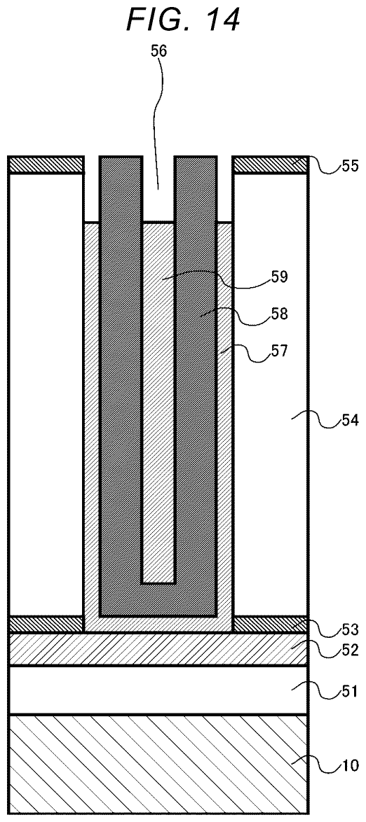

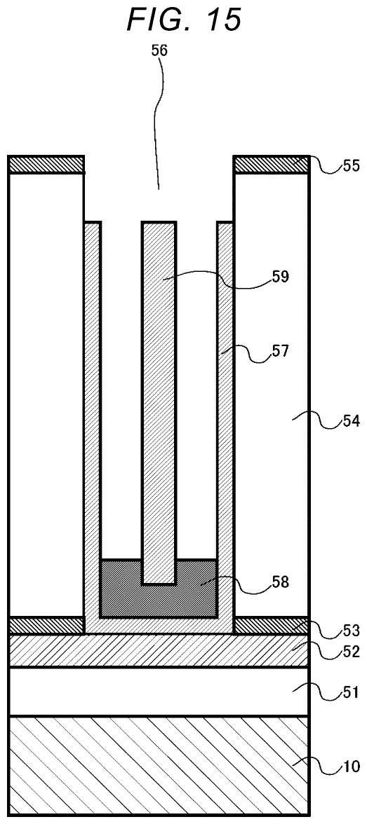

Next, the upper portion of the first titanium nitride film 57 and the upper portion of the second titanium nitride film 59 in the opening 56 are selectively removed with respect to the boron-containing tungsten film 58, e.g., without removing an upper portion of the boron-containing tungsten film 58 (FIG. 14). The first titanium nitride film 57 and the second titanium nitride film 59 are removed, for example, by a wet etching method using hydrofluoric acid. When, for example, silicification treatment is also performed at the time of performing the wet etching using hydrofluoric acid, the surface of the second silicon nitride film 55 is prevented from being etched.

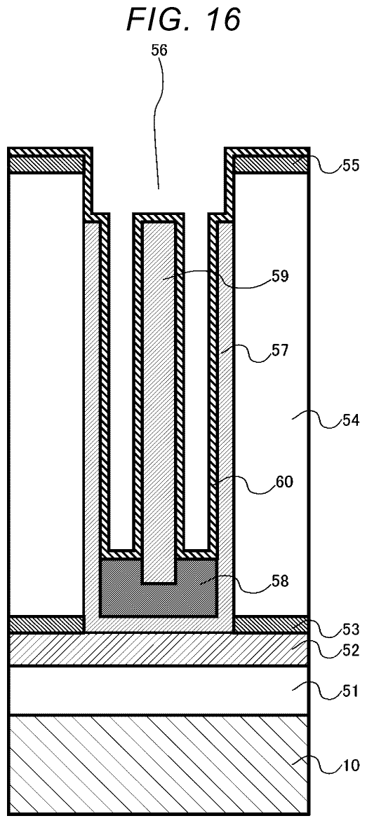

Next, a part of the boron-containing tungsten film 58 in the opening 56 is selectively removed with respect to the first titanium nitride film 57 and the second titanium nitride film 59 (e.g., without removing a part of the first titanium nitride film 57 or a part of the second titanium nitride film 59) to form a pillar structure of the second titanium nitride film 59 (FIG. 15). The boron-containing tungsten film 58 is removed, for example, by a wet etching method using an alkaline chemical solution. The boron-containing tungsten film 58 contains boron. The boron-containing tungsten film 58 contains boron, and thus has a high etching rate at the time of performing the wet etching using an alkaline chemical solution. For example, when a nitrogen-containing tungsten film, an aluminum-containing tungsten film, or a scandium-containing tungsten film is used instead of the boron-containing tungsten film 58, the etching rate increases at the time of performing the wet etching using an alkaline chemical solution.

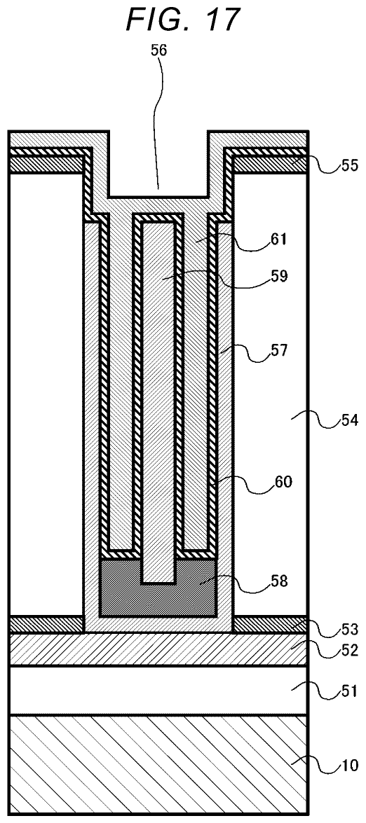

Next, a zirconium oxide film 60 is formed on the first titanium nitride film 57, the boron-containing tungsten film 58, and the second titanium nitride film 59 in the opening 56 (FIG. 16). The zirconium oxide film 60 is formed, for example, using an ALD method. The zirconium oxide film 60 is an example of an insulating film. A part of the zirconium oxide film 60 eventually becomes the first capacitor insulating film 20a.

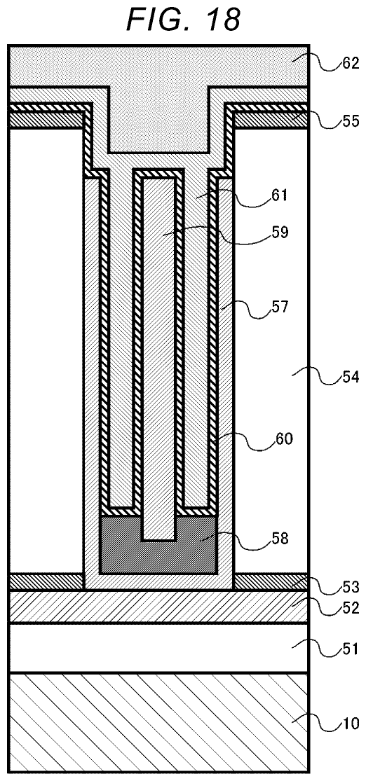

Next, a third titanium nitride film 61 is formed on the zirconium oxide film 60 in the opening 56 (FIG. 17). By forming the third titanium nitride film 61, a space between the first titanium nitride film 57 and the pillar structure of the second titanium nitride film 59 is filled. The third titanium nitride film 61 is formed, for example, using an ALD method. The third titanium nitride film 61 is an example of a fourth conductive film. A part of the third titanium nitride film 61 eventually becomes the first storage node electrode 18a.

Next, an indium tin oxide film 62 is formed on the third titanium nitride film 61 in the opening 56 (FIG. 18). The indium tin oxide film 62 is formed, for example, by a physical vapor deposition method (PVD method). The indium tin oxide film 62 is an example of an oxide conductor film. A part of the indium tin oxide film 62 eventually becomes the first lower electrode 22a.

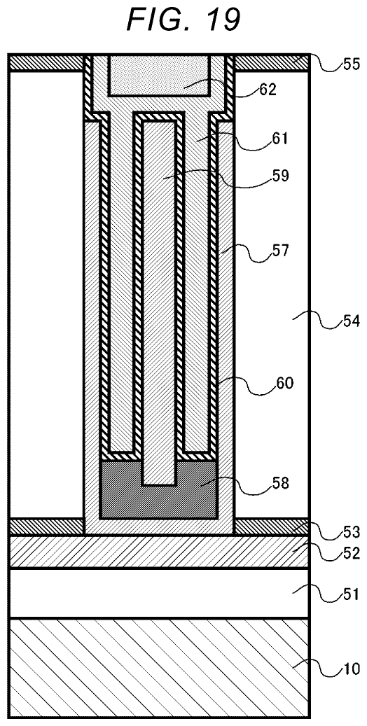

Next, the indium tin oxide film 62, the third titanium nitride film 61, and the zirconium oxide film 60 on the surface of the second silicon nitride film 55 are removed (FIG. 19). The indium tin oxide film 62, the third titanium nitride film 61, and the zirconium oxide film 60 are removed, for example, by a CMP method.

Then, the first transistor TR1 including the first upper electrode 24a, the first oxide semiconductor layer 26a, the first gate electrode 28a, and the first gate insulating film 30a is formed on the zirconium oxide film 60 using a known process technique.

The semiconductor memory 100 including the first memory cell MC1 shown in FIGS. 2, 3, 4, and 5 is manufactured by the above-described manufacturing method.

Next, operations and effects of the semiconductor storage device and the manufacturing method of the semiconductor storage device according to the first embodiment will be described.

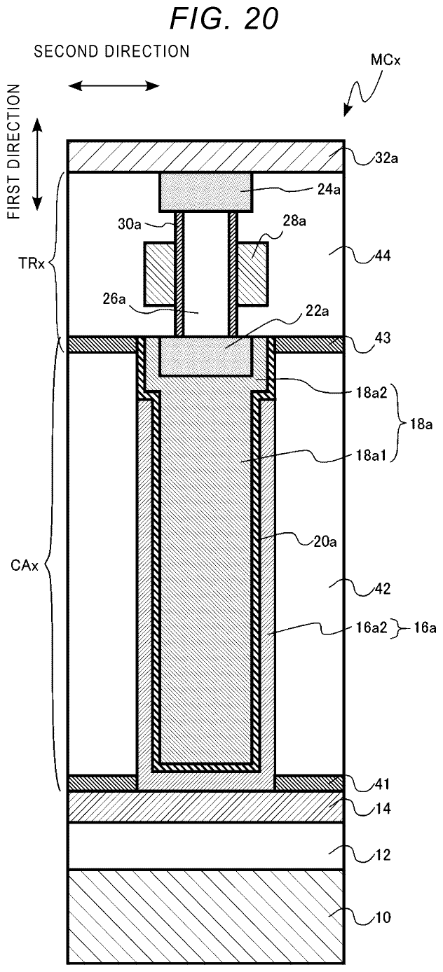

FIG. 20 is a schematic cross-sectional view of a semiconductor storage device according to a comparative example. FIG. 20 is a diagram corresponding to FIG. 2 according to the first embodiment.

The semiconductor storage device according to the comparative example includes a memory cell MCx. The memory cell MCx includes a capacitor CAx and a transistor TRx. The memory cell MCx according to the comparative example differs from the first capacitor CA1 in the first memory cell MC1 according to the first embodiment in that the first plate electrode 16a of the capacitor CAx does not include the pillar portion 16a1 and the bottom portion 16a3.

In the memory cell MCx according to the comparative example, for example, when the memory cell MCx is miniaturized, an opposing area between the first plate electrode 16a and the first storage node electrode 18a of the capacitor CAx becomes smaller, and the capacitance of the capacitor CAx decreases. When the capacitance of the capacitor CAx decreases, the amount of charges stored in the capacitor CAx decreases, and a charge holding time of the memory cell MCx becomes shorter, which causes a problem.

In the first memory cell MC1 according to the first embodiment, the first plate electrode 16a of the first capacitor CA1 includes the pillar portion 16a1 and the bottom portion 16a3. Since the first plate electrode 16a includes the pillar portion 16a1 and the bottom portion 16a3, an opposing area between the first plate electrode 16a and the first storage node electrode 18a is larger than that of the capacitor CAx according to the comparative example. For this reason, the capacitance of the first capacitor CA1 is larger than that of the capacitor CAx according to the comparative example.

Thus, when the first memory cell MC1 is miniaturized, the capacitance of the first capacitor CA1 can be kept larger than that of the capacitor CAx according to the comparative example. Thus, in the first memory cell MC1 according to the first embodiment, a charge holding time of the first memory cell MC1 can be kept longer than that of the memory cell MCx according to the comparative example.

As described above, according to the first embodiment, a DRAM including a capacitor with a large capacitance and a memory cell with excellent charge holding characteristics can be implemented.

In addition, according to the manufacturing method of the semiconductor storage device according to the first embodiment, a DRAM including a capacitor with a large capacitance and a memory cell with excellent charge holding characteristics can be easily manufactured.

### First Modification Example

A semiconductor storage device according to a first modification example of the first embodiment differs from the semiconductor storage device according to the first embodiment in that, in a cross-section parallel to the first direction, a third length of a first capacitor in the second direction perpendicular to the first direction at a first end of a first portion on the side of a third electrode is larger than a fourth length of the first capacitor in the second direction at a second end of the first portion on the side opposite to the third electrode. In addition, there is a difference from the semiconductor storage device according to the first embodiment in that a fifth length of a portion of the first oxide semiconductor layer which is in contact with a fourth electrode in the second direction is larger than a sixth length of a portion of the first oxide semiconductor layer which is in contact with the third electrode in the second direction.

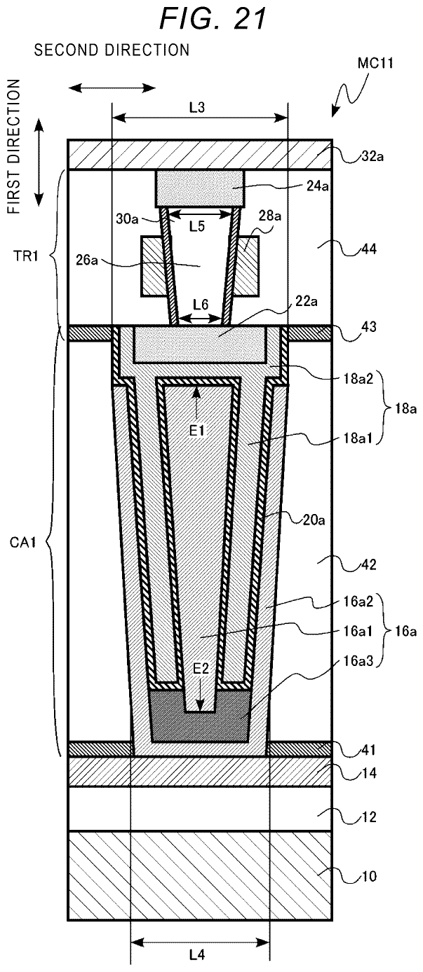

FIG. 21 is a schematic cross-sectional view of the semiconductor storage device according to the first modification example of the first embodiment. FIG. 21 corresponds to FIG. 2 according to the first embodiment.

The semiconductor storage device according to the first modification example of the first embodiment includes a memory cell MC11. The memory cell MC11 includes the first capacitor CA1 and the first transistor TR1.

The length of the first capacitor CA1 in the memory cell MC11 in the second direction becomes smaller toward the substrate 10. The first capacitor CA1 in the memory cell MC11 has a tapered shape.

For example, as shown in FIG. 21, in the first plate electrode 16a, a third length (L3 in FIG. 21) of the first capacitor CA1 in the second direction at a first end (E1 in FIG. 21) of the pillar portion 16a1 on the side of the first lower electrode 22a is longer than a fourth length (L4 in FIG. 21) of the first capacitor CA1 in the second direction at a second end (E2 in FIG. 21) of the pillar portion 16a1 on the side opposite to the first lower electrode 22a.

In addition, the length of the first oxide semiconductor layer 26a of the first transistor TR1 in the second direction becomes smaller toward the first lower electrode 22a from the first upper electrode 24a. The first oxide semiconductor layer 26a has a tapered shape.

For example, a fifth length (L5 in FIG. 21) of a portion of the first oxide semiconductor layer 26a which is in contact with the first upper electrode 24a in the second direction is larger than a sixth length (L6 in FIG. 21) of a portion of the first oxide semiconductor layer 26a which is in contact with the first lower electrode 22a in the second direction.

According to the first modification example of the first embodiment, a DRAM including a capacitor with a large capacitance and a memory cell with excellent charge holding characteristics can be implemented, similar to the first embodiment.

### Second Modification Example

A semiconductor storage device according to a second modification example of the first embodiment differs from the semiconductor storage device according to the first embodiment in that it includes a region containing a metal oxide between a third portion and a first capacitor insulating film.

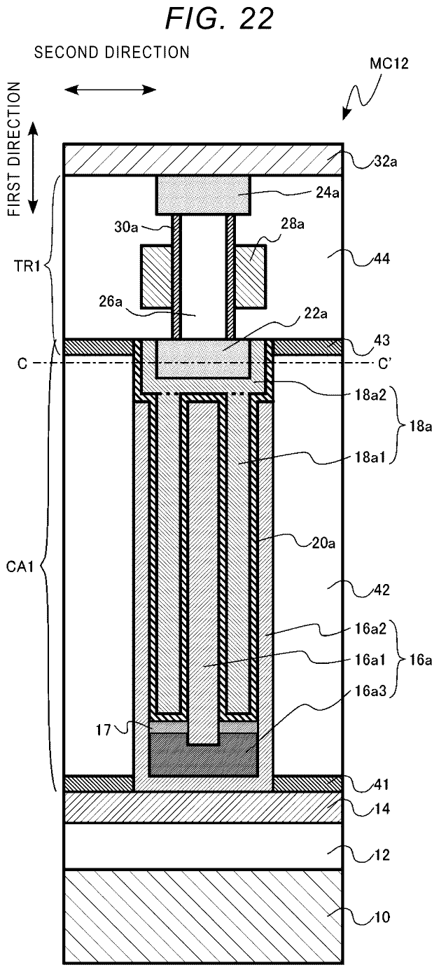

FIG. 22 is a schematic cross-sectional view of the semiconductor storage device according to the second modification example of the first embodiment. FIG. 22 is a diagram corresponding to FIG. 2 according to the first embodiment.

The semiconductor storage device according to the second modification example of the first embodiment includes a memory cell MC12. The memory cell MC12 includes the first capacitor CA1 and the first transistor TR1.

The memory cell MC12 includes a metal oxide region 17 containing a metal oxide. The metal oxide region 17 is an example of a region.

The metal oxide region 17 is provided between the bottom portion 16a3 of the first plate electrode 16a and the first capacitor insulating film 20a. The metal oxide region 17 is in contact with, for example, the bottom portion 16a3 and the first capacitor insulating film 20a. The metal oxide region 17 is a dielectric.

For example, when the bottom portion 16a3 contains tungsten, the metal oxide region 17 contains tungsten oxide. The tungsten oxide can be made into a dielectric by adjusting an oxidation state.

In the manufacturing method of the semiconductor storage device according to the first embodiment, for example, the metal oxide region 17 can be formed by performing oxidation treatment on the surface of the boron-containing tungsten film 58 in the opening 56 before forming the zirconium oxide film 60 on the boron-containing tungsten film 58. The oxidation treatment is performed, for example, under conditions in which the boron-containing tungsten film 58 is selectively oxidized with respect to the first titanium nitride film 57 and the second titanium nitride film 59.

In the semiconductor storage device according to the second modification example of the first embodiment, an effective thickness of the capacitor insulating film is increased by providing the metal oxide region 17, which is a dielectric, between the bottom portion 16a3 and the first capacitor insulating film 20a. For this reason, This reduces electric field concentration at the corner of the lower portion 18a1 of the first storage node electrode 18a on the side of the bottom portion 16a3. Thus, the reliability of the first capacitor insulating film 20a is improved.

According to the second modification example of the first embodiment, a DRAM including a capacitor with a large capacitance and a memory cell with excellent charge holding characteristics can be implemented, similar to the first embodiment. In addition, according to the second modification example of the first embodiment, a DRAM with improved reliability of the capacitor insulating film can be implemented.

As described above, according to the first embodiment and the modification examples, it is possible to implement a semiconductor storage device equipped with an oxide semiconductor transistor having excellent charge holding characteristics by providing a capacitor with a large capacitance, and a manufacturing method thereof.

### Second Embodiment

A semiconductor storage device according to a second embodiment differs from the semiconductor storage device according to the first embodiment in that a first portion and a third portion contain tungsten, the third portion contains boron, the first portion may or may not contain boron, and the boron concentration in the third portion is higher than the boron concentration in the first portion. Repeated contents in the first embodiment will not be described below.

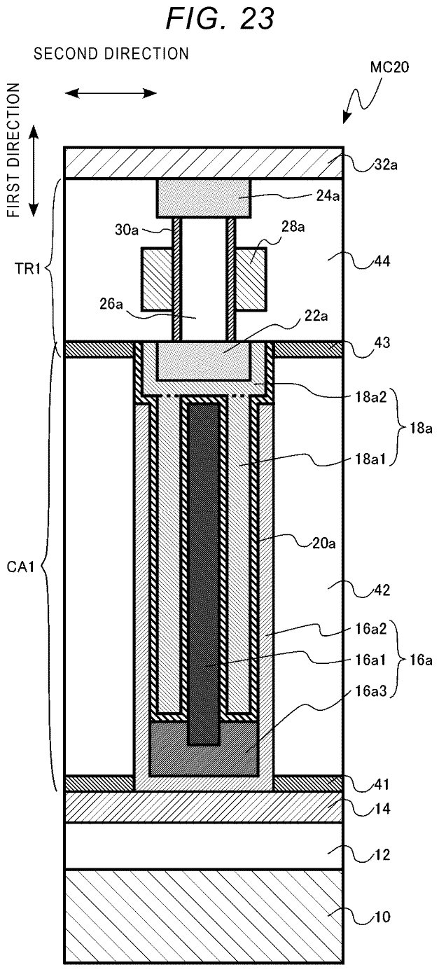

FIG. 23 is a schematic cross-sectional view of the semiconductor storage device according to the second embodiment. FIG. 23 corresponds to FIG. 2 according to the first embodiment.

The semiconductor storage device according to the second embodiment is a semiconductor memory. The semiconductor memory according to the second embodiment includes a memory cell MC20. The memory cell MC20 includes the first capacitor CA1 and the first transistor TR1.

The pillar portion 16a1 of a first plate electrode 16a in the memory cell MC20 contains tungsten. The pillar portion 16a1 is formed of, for example, tungsten. Tungsten is a first material. The tungsten contained in the pillar portion 16a1 may or may not contain boron (B).

The tungsten contained in the pillar portion 16a1 contains, for example, carbon (C).

The outer portion 16a2 of the first plate electrode 16a in the memory cell MC20 contains, for example, titanium nitride. The outer portion 16a2 is formed of, for example, titanium nitride. Titanium nitride is an example of a second material.

The bottom portion 16a3 of the first plate electrode 16a in the memory cell MC20 contains tungsten containing boron (B). The bottom portion 16a3 contains boron-containing tungsten. The bottom portion 16a3 is formed of, for example, boron-containing tungsten.

The concentration of boron (B) in the bottom portion 16a3 is higher than the concentration of boron (B) in the pillar portion 16a1.

The boron-containing tungsten contained in the bottom portion 16a3 may or may not contain carbon (C). The concentration of carbon (C) in the bottom portion 16a3 is, for example, lower than the concentration of carbon (C) in the pillar portion 16a1.

Next, an example of a manufacturing method of the semiconductor storage device according to the second embodiment will be described.

The manufacturing method of the semiconductor storage device according to the second embodiment includes forming an opening in a first insulating layer, forming a first conductive film in the opening, forming a first tungsten film containing boron having a chemical composition different from that of the first conductive film on the first conductive film in the opening, forming a second tungsten film having a boron concentration lower than a boron concentration of the first tungsten film on the first tungsten film in the opening to fill the opening, removing the second tungsten film, the first tungsten film, and the first conductive film on a surface of the first insulating layer, removing an upper portion of the first conductive film, an upper portion of the first tungsten film, and an upper portion of the second tungsten film in the opening, selectively removing a part of the first tungsten film in the opening with respect to the first conductive film and the second tungsten film to form a pillar structure of the second tungsten film, forming an insulating film on the first conductive film, the first tungsten film, and the second tungsten film in the opening, and forming a second conductive film on the insulating film in the opening to fill a space between the first conductive film and the pillar structure. The manufacturing method of the semiconductor storage device according to the second embodiment differs from the manufacturing method of the semiconductor storage device according to the first embodiment in that the second tungsten film is formed instead of a third conductive film.

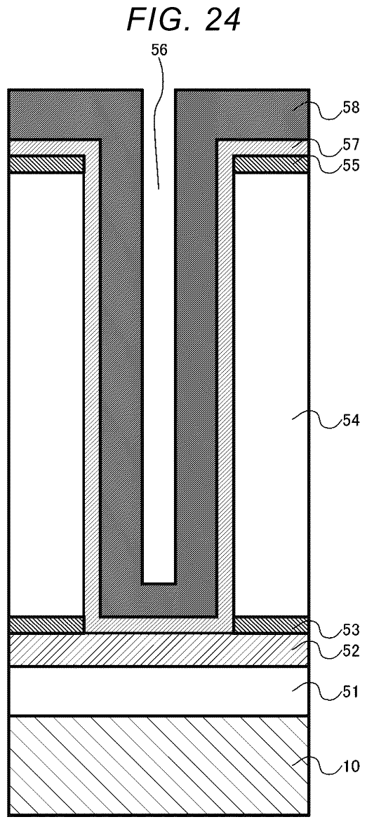

FIGS. 24, 25, 26, 27, 28, 29, and 30 are schematic cross-sectional views showing an example of a manufacturing method of the semiconductor storage device according to the second embodiment. Each of FIGS. 24 to 30 shows a cross-section corresponding to FIG. 23. Each of FIGS. 24 to 30 shows an example of the manufacturing method of the semiconductor storage device according to the second embodiment.

The following is a description of an example in which the substrate insulating layer 12 is made of silicon oxide, the plate conductive layer 14 is made of tungsten, the pillar portion 16a1 of a first plate electrode 16a is made of tungsten, the outer portion 16a2 of the first plate electrode 16a is made of titanium nitride, the bottom portion 16a3 of the first plate electrode 16a is made of boron-containing tungsten, the first storage node electrode 18a is made of titanium nitride, the first capacitor insulating film 20a is made of zirconium oxide, the first lower electrode 22a is made of indium tin oxide, a first interlayer insulating layer 41 and a third interlayer insulating layer 43 are made of silicon nitride, and a second interlayer insulating layer 42 is made of silicon oxide.

The manufacturing method is the same as the manufacturing method of the semiconductor storage device according to the first embodiment up to the formation of the boron-containing tungsten film 58 on the first titanium nitride film 57 in the opening 56 (FIG. 24). The boron-containing tungsten film 58 is formed, for example, by using a CVD method. For example, when forming a tungsten film, diborane (B₂H₆) is used to form a nucleation layer on the first titanium nitride film 57, thereby forming the boron-containing tungsten film 58. The boron concentration in the boron-containing tungsten film 58 can be adjusted by adjusting the flow rate of diborane (B₂H₆). The boron-containing tungsten film 58 is an example of a first tungsten film. A part of the boron-containing tungsten film 58 eventually becomes the bottom portion 16a3 of the first plate electrode 16a.

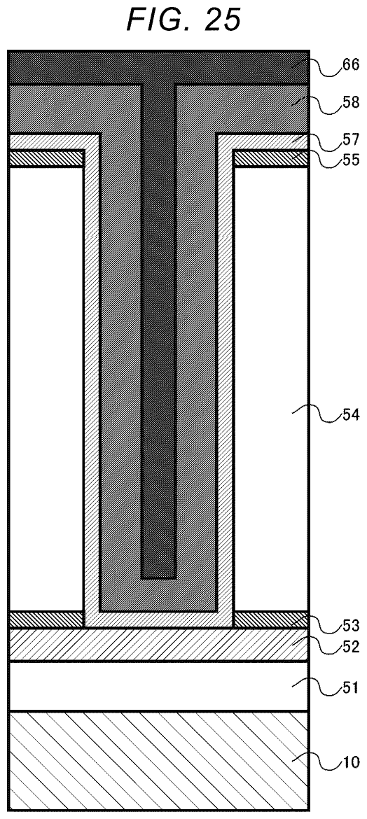

Next, a tungsten film 66 is formed on the boron-containing tungsten film 58 in the opening 56 to fill the opening 56 (FIG. 25). The tungsten film 66 may or may not contain boron (B). The boron concentration of the tungsten film 66 is lower than the boron concentration of the boron-containing tungsten film 58. The tungsten film 66 is formed continuously with the boron-containing tungsten film 58, for example, by a CVD method. The tungsten film 66 can also be formed, for example, by an ALD method after the formation of the boron-containing tungsten film 58.

The tungsten film 66 is an example of a second tungsten film. The tungsten film 66 eventually becomes the pillar portion 16a1 of the first plate electrode 16a.

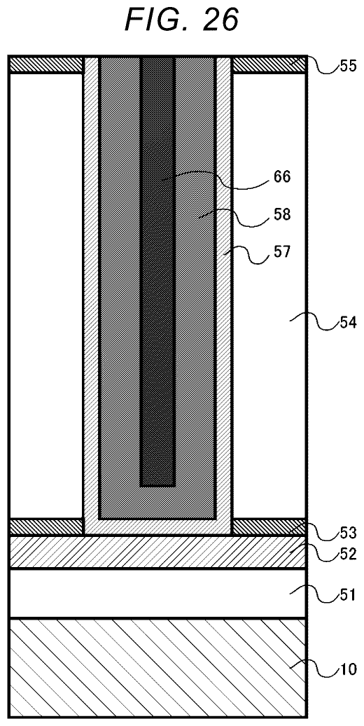

Next, the tungsten film 66, the boron-containing tungsten film 58, and the first titanium nitride film 57 on the surface of the second silicon nitride film 55 are removed (FIG. 26). The tungsten film 66, the boron-containing tungsten film 58, and the first titanium nitride film 57 are removed, for example, by a CMP method.

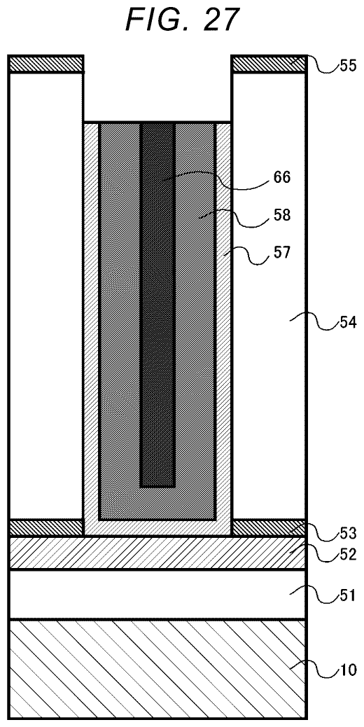

Next, the upper portion of the tungsten film 66, the upper portion of the boron-containing tungsten film 58, and the upper portion of the first titanium nitride film 57 in the opening 56 are removed (FIG. 27). The tungsten film 66, the boron-containing tungsten film 58, and the first titanium nitride film 57 are removed, for example, by a wet etching method using hydrogen peroxide. By using the wet etching method using hydrogen peroxide, a difference in etching rate between the tungsten film 66, the boron-containing tungsten film 58, and the first titanium nitride film 57 can be reduced.

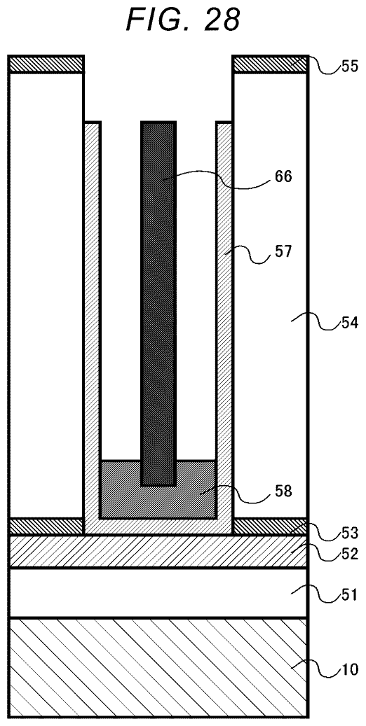

Next, a part of the boron-containing tungsten film 58 in the opening 56 is selectively removed with respect to the first titanium nitride film 57 and the tungsten film 66 (e.g., without removing a part of the first titanium nitride film 57 or a part of the tungsten film 66) to form a pillar structure of the tungsten film 66 (FIG. 28). The boron-containing tungsten film 58 is removed, for example, by a wet etching method using an alkaline chemical solution. The boron-containing tungsten film 58 contains a high concentration of boron, and thus an etching rate at the time of the wet etching using the alkaline chemical solution is higher than an etching rate of the tungsten film 66, which has a low boron concentration.

For example, when the tungsten film 66 contains carbon (C), the etching rate at the time of the wet etching using the alkaline chemical solution is lower than when the tungsten film 66 does not contain carbon (C). Thus, when the tungsten film 66 contains carbon (C), a difference between the etching rate of the boron-containing tungsten film 58 and the etching rate of the tungsten film 66 becomes further higher.

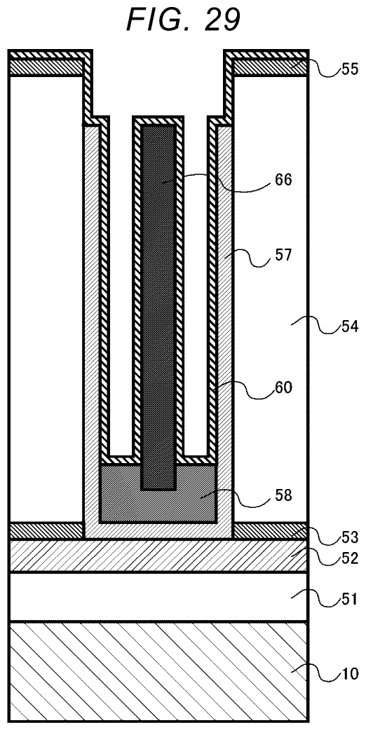

Next, the zirconium oxide film 60 is formed on the first titanium nitride film 57, the boron-containing tungsten film 58, and the tungsten film 66 in the opening 56 (FIG. 29). The zirconium oxide film 60 is formed, for example, by an ALD method. The zirconium oxide film 60 is an example of an insulating film. A part of the zirconium oxide film 60 eventually becomes the first capacitor insulating film 20a.

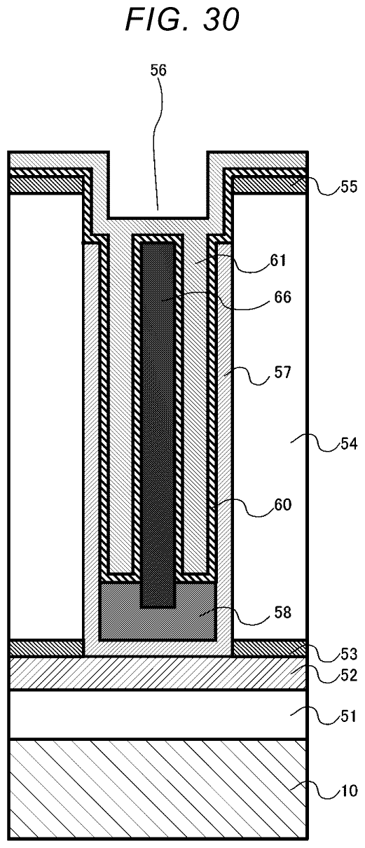

Next, the third titanium nitride film 61 is formed on the zirconium oxide film 60 in the opening 56 (FIG. 30). By forming the third titanium nitride film 61, a space between the first titanium nitride film 57 and the pillar structure of the tungsten film 66 is filled. The third titanium nitride film 61 is formed, for example, using an ALD method. The third titanium nitride film 61 is an example of a second conductive film. A part of the third titanium nitride film 61 eventually becomes the first storage node electrode 18a.

Thereafter, the first transistor TR1 including the first lower electrode 22a, the first upper electrode 24a, the first oxide semiconductor layer 26a, the first gate electrode 28a, and the first gate insulating film 30a is formed on the zirconium oxide film 60 by a manufacturing method similar to that of the semiconductor storage device according to the first embodiment.

The semiconductor memory including the memory cell MC20 shown in FIG. 23 is manufactured by the above-described manufacturing method.

As described above, according to the second embodiment, as in the first embodiment, it is possible to implement a semiconductor storage device equipped with an oxide semiconductor transistor having excellent charge holding characteristics by providing a capacitor with a large capacitance, and a manufacturing method thereof.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor storage device comprising:
a first capacitor that includes a first electrode, a second electrode, and a first capacitor insulating film provided between the first electrode and the second electrode; and
a first transistor that includes a third electrode in contact with the second electrode, a fourth electrode, a first oxide semiconductor layer provided between the third electrode and the fourth electrode, a first gate electrode facing the first oxide semiconductor layer, and a first gate insulating film provided between the first gate electrode and the first oxide semiconductor layer, wherein
the first transistor and the first capacitor are arranged in a first direction,
the first electrode includes a first portion having a first chemical composition, a second portion having a second chemical composition, and a third portion having a third chemical composition,
the first chemical composition of the first portion is different from the third chemical composition of the third portion,
the second chemical composition of the second portion is different from the third chemical composition of the third portion,
the first portion is provided between the third portion and the third electrode in the first direction,
the second electrode includes a fourth portion, and
in a first cross-section perpendicular to the first direction, the second portion surrounds the fourth portion and the fourth portion surrounds the first portion.

2. The semiconductor storage device according to claim 1, wherein
in a second cross-section perpendicular to the first direction,
the second portion surrounds the third portion, and the third portion surrounds the first portion, and
the second portion is in contact with the third portion, and the third portion is in contact with the first portion.

3. The semiconductor storage device according to claim 1, wherein at least a portion of the third portion is provided between at least a portion the second portion and the first portion in the first direction.

4. The semiconductor storage device according to claim 1, wherein
the second electrode includes a fifth portion provided between the fourth portion and the third electrode, and
in a third cross-section perpendicular to the first direction, the fifth portion surrounds the third electrode.

5. The semiconductor storage device according to claim 4, wherein the third electrode includes an oxide conductor.

6. The semiconductor storage device according to claim 4, wherein
the fifth portion has an outer diameter, and
the first portion has a first length in the first direction that is 10 times or more the outer diameter of the fifth portion.

7. The semiconductor storage device according to claim 1, wherein
the first capacitor has a fourth length in the second direction at a second end of the first portion on a side opposite to the third electrode in a cross-section parallel to the first direction, and
the first capacitor has a third length in a second direction perpendicular to the first direction at a first end of the first portion on a side of the third electrode,
the third length of the first capacitor is larger than the fourth length of the first capacitor.

8. The semiconductor storage device according to claim 7, wherein
the first oxide semiconductor layer is in contact with the third electrode and the fourth electrode,
a portion of the first oxide semiconductor layer which is in contact with the third electrode in the second direction has a sixth length, and
a portion of the first oxide semiconductor layer which is in contact with the fourth electrode in the second direction has a fifth length that is larger than the sixth length of the portion of the first oxide semiconductor layer.

9. The semiconductor storage device according to claim 1, wherein
the first portion and the second portion contain titanium nitride, and
the third portion contains tungsten containing at least one element selected from a group including boron (B), nitrogen (N), aluminum (Al), and scandium (Sc).

10. The semiconductor storage device according to claim 1, comprising a region containing a metal oxide between the third portion and the first capacitor insulating film.

11. The semiconductor storage device according to claim 1, wherein
the first portion and the third portion contain tungsten,
the third portion contains boron, and the first portion contains or does not contain boron, and
a boron concentration of the third portion is higher than a boron concentration of the first portion.

12. The semiconductor storage device according to claim 1, further comprising:
a second capacitor that includes a fifth electrode, a sixth electrode, and a second capacitor insulating film provided between the fifth electrode and the sixth electrode;
a second transistor that includes a seventh electrode in contact with the sixth electrode, an eighth electrode, a second oxide semiconductor layer provided between the seventh electrode and the eighth electrode, a second gate electrode facing the second oxide semiconductor layer, and a second gate insulating film provided between the second gate electrode and the second oxide semiconductor layer, wherein the second transistor and the second capacitor are arranged in the first direction;
a first conductive layer that is in contact with the first electrode and the fifth electrode; and
a second conductive layer that is electrically connected to the fourth electrode and the eighth electrode.

13. The semiconductor storage device according to claim 1, further comprising:
a third capacitor that includes a ninth electrode, a tenth electrode, and a third capacitor insulating film provided between the ninth electrode and the tenth electrode;
a third transistor that includes an eleventh electrode in contact with the tenth electrode, a twelfth electrode, a third oxide semiconductor layer provided between the eleventh electrode and the twelfth electrode, a third gate electrode facing the third oxide semiconductor layer, and a third gate insulating film provided between the third gate electrode and the third oxide semiconductor layer, wherein the third transistor is provided in the first direction with respect to the third capacitor; and
a first conductive layer that is in contact with the first electrode and the ninth electrode,
wherein the first gate electrode and the third gate electrode are electrically connected to each other.

14. A manufacturing method of a semiconductor storage device, the manufacturing method comprising:
forming an opening in a first insulating layer;
forming a first conductive film in the opening;
forming a second conductive film having a chemical composition different from a chemical composition of the first conductive film on the first conductive film in the opening;
forming a third conductive film having a chemical composition different from a chemical composition of the second conductive film on the second conductive film in the opening to fill the opening;
removing the third conductive film, the second conductive film, and the first conductive film on a surface of the first insulating layer;
selectively removing an upper portion of the first conductive film and an upper portion of the third conductive film in the opening without removing an upper portion of the second conductive film;
selectively removing a part of the second conductive film in the opening without removing a part of the first conductive film or a part of the third conductive film, to form a pillar structure of the third conductive film;
forming an insulating film on the first conductive film, the second conductive film, and the third conductive film in the opening; and
forming a fourth conductive film on the insulating film in the opening to fill a space between the first conductive film and the pillar structure.

15. The manufacturing method of the semiconductor storage device according to claim 14, comprising:
forming the fourth conductive film and then forming an oxide conductor film on the fourth conductive film in the opening to fill the opening; and
removing the oxide conductor film, the fourth conductive film, and the insulating film on the surface of the first insulating layer.

16. The manufacturing method of the semiconductor storage device according to claim 14, wherein the third conductive film, the second conductive film, and the first conductive film on the surface of the first insulating layer are removed using a chemical mechanical polishing (CMP) method.

17. The manufacturing method of the semiconductor storage device according to claim 15, wherein the oxide conductor film, the fourth conductive film, and the insulating film on the surface of the first insulating layer are removed by a chemical mechanical polishing (CMP) method.

18. The manufacturing method of the semiconductor storage device according to claim 14, wherein
the first conductive film and the third conductive film contain titanium nitride, and
the second conductive film contains tungsten containing boron.

19. A manufacturing method of a semiconductor storage device, comprising:
forming an opening in a first insulating layer;
forming a first conductive film in the opening;
forming a first tungsten film having a chemical composition different from that of the first conductive film and containing boron on the first conductive film in the opening;
forming a second tungsten film having a boron concentration lower than a boron concentration of the first tungsten film on the first tungsten film in the opening to fill the opening;
removing the second tungsten film, the first tungsten film, and the first conductive film on a surface of the first insulating layer;
removing an upper portion of the first conductive film, an upper portion of the first tungsten film, and an upper portion of the second tungsten film in the opening;
selectively removing a part of the first tungsten film in the opening without a part of the first conductive film or a part of the second tungsten film, to form a pillar structure of the second tungsten film;
forming an insulating film on the first conductive film, the first tungsten film, and the second tungsten film in the opening; and
forming a second conductive film on the insulating film in the opening to fill a space between the first conductive film and the pillar structure.

20. The manufacturing method of the semiconductor storage device according to claim 19, wherein the first tungsten film and the second tungsten film are formed successively using a chemical vapor deposition (CVD) method.

21. The manufacturing method of the semiconductor storage device according to claim 19, wherein a part of the first tungsten film is removed by a wet etching method using an alkaline chemical solution.

22. The manufacturing method of the semiconductor storage device according to claim 19, wherein the first conductive film contains titanium nitride.
